(19) United States
(12) Patent Application Publication
(10) Pub. No.: US 2025/0275429 A1
(43) Pub. Date: Aug. 28, 2025

(54) DISPLAY DEVICE

(71) Applicant: LG DISPLAY CO., LTD., Seoul (KR)

(72) Inventors: Seong Woo PARK, Paju-si (KR); Seung Han PAEK, Paju-si, Gyeonggi-do (KR); Hyun Jin AN, Paju-si, Gyeonggi-do (KR)

(73) Assignee: LG DISPLAY CO., LTD., Seoul (KR)

(21) Appl. No.: 19/001,275

(22) Filed: Dec. 24, 2024

(30) Foreign Application Priority Data
Feb. 23, 2024 (KR) 10-2024-0026596

(51) Int. Cl. H10K 59/80; H10K 102/00

(52) U.S. Cl. CPC H10K 59/873; H10K 2102/311

(57) ABSTRACT

A display device includes a folding region and a plurality of non-folding regions. The display device includes a substrate; a circuit layer on the substrate to drive pixels; a light-emitting element layer on the circuit layer; an encapsulation layer covering the circuit layer and the light-emitting element layer; and a cover glass on the encapsulation layer, wherein the substrate includes a buffer section in the folding region, and at least two auxiliary buffer sections spaced apart from the buffer section with the buffer section interposed between the at least two auxiliary buffer sections.

This application claims priority to and the benefit of Korean Patent Application No. 10-2024-0026596, filed Feb. 23, 2024, the disclosure of which is incorporated herein by reference in its entirety.

### BACKGROUND

### Technical Field

The present disclosure relates to a display device, and more particularly, to a foldable display device.

### Discussion of the Related Art

Electroluminescence display devices are classified into inorganic light-emitting display devices and organic light-emitting display devices depending on materials of an emission layer. An active-matrix-type organic light-emitting display device includes an organic light-emitting diode (OLED) that emits light by itself and has advantages of a quick response time, high light emission efficiency, high luminance, and a wide viewing angle. The organic light-emitting display device has OLEDs formed in each pixel. The organic light-emitting display device may represent a black grayscale as perfect black as well as having a quick response time, high light emission efficiency, high luminance, and a wide viewing angle, and thus has an excellent contrast ratio and color gamut.

The organic light-emitting display device does not require a backlight unit, and may be implemented on a plastic substrate, a thin glass substrate, or a metal substrate, which is a flexible material. Therefore, the flexible display may be implemented as an organic light-emitting display device.

The size of the screen of a flexible display may be changed by wrapping, folding, or bending the flexible panel. The flexible display may be implemented as a rollable display, a foldable display, a bendable display, a slideable display, or the like.

Because a foldable display continuously experience stress on the folding surface due to repeated folding, there is a high possibility of damage and crease occurring in a region where maximum stress, or at least a large stress, is applied.

Accordingly, there is a demand for a display that reduces or distributes stress in a region where stress is maximally, or at least greatly, applied due to repeated folding.

### SUMMARY

Accordingly, embodiments of the present disclosure are directed to a display device that substantially obviates one or more of the problems due to limitations and disadvantages of the related art.

An aspect of the present disclosure is to provide a display panel that is structurally strong in response to stress caused by repeated folding, and a display device including the display panel.

Another aspect of the present disclosure is to provide a display panel that minimizes or at least reduces stress applied to the light-emitting element layer by regulating the thickness in the folding region and moving the neutral plane correspondingly, and a display device including the display panel.

Another aspect of the present disclosure is to provide a display panel that is structurally improved to prevent damage caused by an etching process and to allow the position of the neutral plane to be regulated, and a display device including the display panel.

Another aspect of the present disclosure is to provide a display panel that implements process optimization, or at least improvement, and a display device including the display panel.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device, including a folding region and a plurality of non-folding regions, comprises a substrate; a circuit layer on the substrate to drive pixels; a light emitting element layer on the circuit layer; an encapsulation layer covering the circuit layer and the light-emitting element layer; and a cover glass on the encapsulation layer, wherein the substrate includes a buffer section in the folding region, and at least two auxiliary buffer sections spaced apart from the buffer section with the buffer section interposed between the at least two auxiliary buffer sections.

In another aspect, a display device, including at least two folding regions and a plurality of non folding regions, comprises a substrate; a circuit layer on the substrate to drive pixels; a light-emitting element layer on the circuit layer; an encapsulation layer covering the circuit layer and the light-emitting element layer; and a cover glass on the encapsulation layer, wherein the non-folding regions include a first non-folding region, a second non-folding region, and a third non-folding region, wherein the folding regions include a first folding region between the first non-folding region and the second non-folding region, and a second folding region between the second non-folding region and the third non-folding region, and wherein the substrate includes a first buffer section in the first folding region, a second buffer section in the second folding region, at least two first auxiliary buffer sections spaced apart from the first buffer section with the first buffer section interposed between the at least two first auxiliary buffer sections, and at least two second auxiliary buffer sections apart from the second buffer section with the second buffer section interposed between the at least two first auxiliary buffer sections.

Embodiments of the present disclosure may improve rigidity through a glass substrate and reduce the degree of deformation in the folding region through holes and grooves formed in the substrate so that the display panel may be structurally strengthened in response to stress applied to the folding region. Consequently, the possibility of a crease or the like being forming on the display panel may be minimized or at least reduced.

Embodiments of the present disclosure may minimize or at least reduce stress applied to the light-emitting element layer by regulating the thickness in the folding region and moving the neutral plane correspondingly. Consequently, the possibility of a crease or the like being forming on the display panel may be minimized or at least reduced.

Embodiments of the present disclosure may use an organic film disposed on the substrate to prevent damage caused by an etching process and to regulate the position of the neutral plane.

Embodiments of the present disclosure may implement process of optimization, or at least improvement, by etching grooves and holes in the substrate through a single etching process.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a view illustrating the folded state of a display device according to an embodiment of the present disclosure;

FIG. 2 is a perspective view illustrating the display panel of a display device according to an embodiment of the present disclosure;

FIG. 3 is a front view illustrating the display panel of a display device according to an embodiment of the present disclosure;

FIG. 4 is a view illustrating the arrangement relationship between a buffer section and auxiliary buffer sections disposed on the display panel of the display device in the folded state according to an embodiment of the present disclosure;

FIG. 5 is a view illustrating the neutral plane according to folding;

FIG. 6A is a cross-sectional view taken along line I-I′ in FIG. 2;

FIG. 6B is an enlarged view of region B in FIG. 6A;

FIG. 7 is a view showing another example of the display panel disposed in a display device according to an embodiment of the present disclosure;

FIG. 8 is a view showing another example of the display panel disposed in a display device according to an embodiment of the present disclosure;

FIG. 9 is a view showing another example of the display panel disposed in a display device according to an embodiment of the present disclosure;

FIG. 10 is a graph showing the degree of deformation in the folding region according to embodiments of the display panel;

FIG. 11 is a perspective view illustrating the display panel of a display device according to another embodiment of the present disclosure;

FIG. 12 is a view illustrating the folded state of the display panel disposed in a display device according to another embodiment of the present disclosure;

FIG. 13 is an enlarged view of regions D and E in FIG. 12;

FIG. 14 is a front view illustrating the display panel disposed in a display device according to another embodiment of the present disclosure;

FIG. 15 is a view showing another example of the display panel disposed in a display device according to another embodiment of the present disclosure; and

FIG. 16 is a view showing another example of the display panel disposed in a display device according to another embodiment of the present disclosure.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

Shapes, sizes, ratios, angles, numbers, and the like disclosed in the drawings for describing the embodiments of the present disclosure are exemplary, and the present disclosure is not limited to the illustrated items. Like reference numerals refer to like elements throughout. In addition, in describing the present disclosure, if it is determined that the detailed description of the related known technology may unnecessarily obscure the subject matter of the present disclosure, the detailed description thereof will be omitted.

The terms such as “comprising,” “including,” “having,” and “consisting of” used herein are generally intended to allow other components to be added unless the terms are used with the term “only.” References to the singular shall be construed to include the plural unless expressly stated otherwise.

In interpreting a component, it is interpreted to include an error range even if there is no separate description.

When describing a positional or interconnected relationship between two components, such as “on top of,” “above,” “below,” “next to,” “connect or couple with,” “crossing,” “intersecting,” etc., one or more other components may be interposed between them unless “immediately” or “directly” is used.

When describing a temporal contextual relationship is described, such as “after,” “following,” “next to,” or “before,” it may not be continuous on a time scale unless “immediately” or “directly” is used.

The terms “first,” “second,” and the like may be used to distinguish components from each other, but the functions or structures of the components are not limited by ordinal numbers or component names in front of the components.

The following embodiments may be combined or associated with each other in whole or in part, and various types of interlocking and driving are technically possible. The embodiments may be implemented independently of each other or together in an interrelated relationship.

Hereinafter, preferred embodiments of the present disclosure will be described in detail with reference to the accompanying drawings.

As used herein, “a display apparatus” may include a display apparatus in a narrow sense, such as a liquid crystal module (LCM), an organic light-emitting diode (OLED) module, or a quantum dot (QD) module, which includes a display panel and a driver for driving the display panel. It may also include a set electronic apparatus or a set device or set apparatus, such as a laptop computer, a television set, a computer monitor, an automotive display apparatus or an equipment display apparatus including another form in a vehicle, and a mobile electronic apparatus, such as a smart phone or an electronic pad, which is a complete product or finished product including the LCM, the OLED module, and the QD module.

The display device may include a display device itself in a narrow sense, an application product including a display in a narrow sense, or even a set device being an end-consumer device.

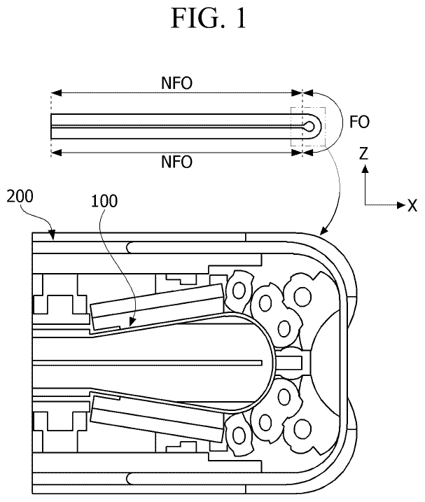

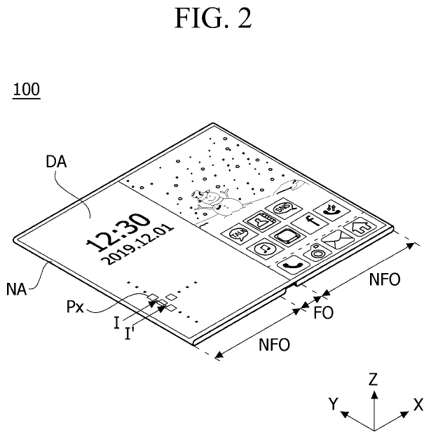

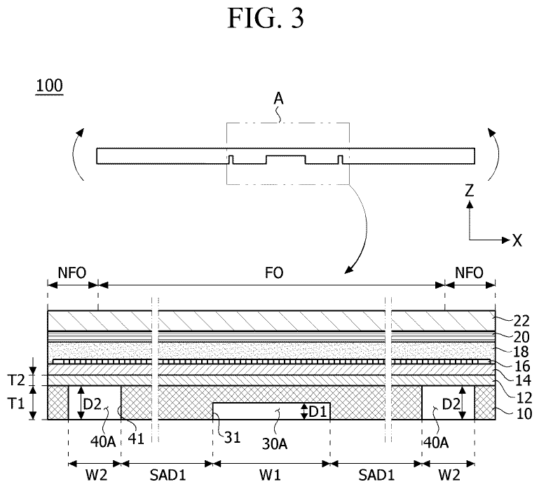

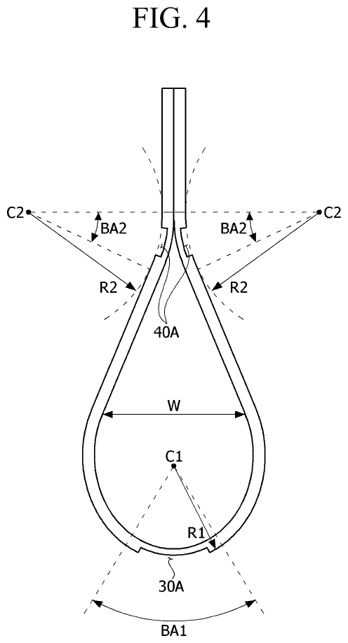

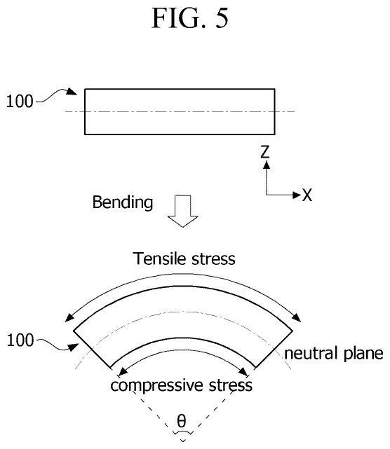

FIG. 1 is a view illustrating the folded state of a display device according to an embodiment of the present disclosure; FIG. 2 is a perspective view illustrating the display panel of a display device according to an embodiment of the present disclosure; FIG. 3 is a front view illustrating the display panel of a display device according to an embodiment of the present disclosure; FIG. 4 is a view illustrating the arrangement relationship between a buffer section and auxiliary buffer sections disposed on the display panel of the display device in the folded state according to an embodiment of the present disclosure; and FIG. 5 is a view illustrating the neutral plane according to folding. The display panel 100 shown in FIG. 3 may represent a display panel according to a first embodiment. Additionally, FIG. 4 may be a conceptual view showing the folded state of region A in FIG. 3.

With reference to FIGS. 1 to 4, the display device according to an embodiment of the present disclosure may include a display panel 100 on which an input image is visually reproduced, a case 200 to accommodate the display panel 100, and a mechanism, such as a hinge for folding the display panel 100. Here, the display panel 100 and the case 200 may constitute the external appearance of the display device. Additionally, the display panel 100 may include a folding region FO and non-folding regions NFO, and the folding region FO may be bent or folded with respect to the center of the folding region FO by an external force. Here, the folding region FO may be formed in a folding line crossing from one end of the display panel 100 to the other end thereof along the length or width direction.

With reference to FIG. 2, the display panel 100 may include a display area DA where an image is displayed and a non-display area NA where an image is not displayed. Here, the display panel 100 may be a panel with a rectangular structure having a length in the X-axis direction, a width in the Y-axis direction, and a thickness in the Z-axis direction. At this time, the width and length of the display panel 100 may be set to various design values depending on the application field of the display device. Additionally, the X-axis direction may mean the length direction, row direction, or horizontal direction; the Y-axis direction may mean the width direction, column direction, or vertical direction; and the Z-axis direction may mean a vertical direction or thickness direction. Further, the X-axis direction, Y-axis direction, and Z-axis direction may be perpendicular to each other, but may also mean different directions that are not perpendicular to each other. Hence, each of the X-axis direction, Y-axis direction, and Z-axis direction may be described as one of a first direction, a second direction, and a third direction. And, the surface extended in the X-axis direction and the Y-axis direction may mean a horizontal surface.

In the display area DA of the display panel 100, data lines, gate lines crossing the data lines, and pixels Px arranged in a matrix form defined by the data lines and the gate lines may be disposed. Each of the pixels Px includes sub-pixels of different colors for color implementation. The sub-pixels include a red sub-pixel, a green sub-pixel, and a blue sub-pixel. Although not shown, each of the pixels Px may further include a white sub-pixel. In the following description, a pixel may be interpreted as a sub-pixel unless otherwise defined. Additionally, each of sub-pixels may include a pixel circuit.

The pixel circuit may include a light-emitting element, a driving element that supplies a current to the light-emitting element, one or more switch elements that switch the current paths of the driving element and the light-emitting element, and a capacitor that maintains the voltage Vgs between the gate and the source of the driving element. The light-emitting elements may be implemented in an element structure, such as organic light-emitting diode (OLED) display, quantum dot display, and micro light-emitting diode (micro LED) display. In the following description, the light-emitting elements will be described as an OLED structure including an organic compound layer.

The OLED includes an organic compound layer formed between the anode and the cathode. The organic compound layer may include, but not limited to, a hole injection layer (HIL), a hole transport layer (HTL), an emission layer (EML), an electron transport layer (ETL), and an electron injection layer (EIL). When a voltage is applied to the anode electrode and the cathode electrode of the OLED, holes passing through the hole transport layer (HTL) and electrons passing through the electron transport layer (ETL) are moved to the emission layer (EML) to form excitons, thereby emitting visible light in the emission layer (EML).

The display panel driver writes pixel data of the input image to pixels Px. The display panel driver includes a data driver that supplies a data voltage of pixel data to the data lines, and a gate driver that sequentially supplies a gate pulse to the gate lines. The data driver is integrated into a drive IC. The drive IC may be attached to the display panel 100.

The drive IC is connected to the data lines through data output channels and supplies the voltage of the data signal to the data lines. The drive IC includes a timing controller. The timing controller transfers pixel data of the input image received from the host system to the data driver and controls the operation timing of the data driver and the gate driver. The data driver of the drive IC converts pixel data into a gamma compensation voltage through a digital to analog converter (DAC) to output a data voltage.

The gate driver may include a shift register formed in the circuit layer of the display panel 100 along with the pixel array. The shift register of the gate driver sequentially supplies gate signals to the gate lines under the control of the timing controller. The gate signals may include a scan pulse and an emission control pulse (hereinafter referred to as “EM pulse”). The shift register may include a scan driver that outputs scan pulses and an EM driver that outputs EM pulses.

The host system may be implemented with an application processor (AP). The host system transfers pixel data of the input image to the drive IC. The host system may be connected to the drive IC via a flexible printed circuit (FPC), for example.

In the non-display area NA, various wiring lines and driving circuits may be disposed, and the pad part to which integrated circuits and printed circuits are connected may be disposed.

The flexible printed circuit (FPC) may be formed on a flexible printed circuit board and may be connected to the drive IC through the pad part. Here, the drive IC may be disposed on the display panel 100, but without being limited thereto. For example, the drive IC may be disposed on the flexible printed circuit board.

The substrate disposed on the display panel 100 may be made of a flexible polyimide (PI) film substrate. However, because the PI film substrate is partially separated through a laser lift off process using a laser equipment, defects may occur during the process due to foreign matter resulting from peeling-off and roughness on the surface of the PI film substrate. In addition, because the PI film substrate is relatively less rigid than a glass substrate, creases or hinge stains may be formed due to repeated folding. Accordingly, the display panel 100 may be manufactured based on a glass substrate in consideration of prevention of a defect caused by the process of peeling off the PI film, rigidity, or the like. Consequently, the glass substrate may improve rigidity in the folding region and prevent formation of a crease or hinge stain. Here, the substrate may be a glass film with a thickness of 0.2 mm or less, but without being limited thereto. For example, the thickness of a glass substrate may be regulated through an etching process.

With reference to FIG. 3, the display panel 100 according to the first embodiment includes a substrate 10, a circuit layer 14 disposed on the substrate 10, and a light-emitting element layer 16.

In addition, the display panel 100 according to the first embodiment may further include an organic film 12 disposed between the substrate 10 and the circuit layer 14. In addition, the display panel 100 according to the first embodiment may further include an encapsulation layer 18 that covers the circuit layer 14 and the light emitting element layer 16, a polarizer 20, and a cover glass 22. In addition, a touch screen on which touch sensors are arranged may be implemented on the display panel 100 according to the first embodiment. Wires of touch sensors (not shown) may be disposed between the encapsulation layer 18 and the polarizer 20.

With reference to FIGS. 3 and 4, the display panel 100 including a folding region FO and non-folding regions NFO may be folded to have a water drop-shaped cross section. Accordingly, the width W of the display panel 100 in the folding region FO may become smaller as it moves toward the non-folding region NFO.

The folded display panel 100 may include a plurality of bending regions with different bending degrees. As shown in FIG. 4, the folded display panel 100 may include a first bending region BA1 and two second bending regions BA2 having different curvatures, and the second bending regions BA2 are arranged to be spaced apart from the first bending region BA1.

The first bending region BA1 is a region of the display panel 100 where the buffer section 30A is disposed, and may be formed to have a first curvature 1/R1 with respect to the virtual center of curvature C1. In addition, the second bending region BA2 is a region of the display panel 100 where the auxiliary buffer section 40A is disposed, and may be formed to have a second curvature 1/R2 with respect to the virtual center of curvature C2. Here, the radius of curvature R1 of the first bending region BA1 and the radius of curvature R2 of the second bending region BA2 may be the distances from the virtual centers of curvature C1 and C2 to the rear surface of the bent substrate 10.

The center of curvature C1 of the first bending region BA1 is disposed closer to the cover glass 22 than the substrate 10, and the center of curvature C2 of the second bending region BA2 is disposed closer to the substrate 10 than the cover glass 22. For example, with respect to the folded display panel 100, the center of curvature C1 of the first bending region BA1 may be disposed on the inside, and the center of curvature C2 of the second bending region BA2 may be disposed on the outside adjacent to the case 200.

Because the curvature 1/R1 of the first bending region BA1 is greater than the curvature 1/R2 of the second bending region BA2, the display panel 100 forms a relatively gentler curved surface in the second bending region BA2 than in the first bending region BA1. Consequently, the positions of the neutral plane in the individual bending regions BA1 and BA2 may be different, and the stress applied to the individual bending regions BA1 and BA2 may be different.

With reference to FIG. 5, the neutral plane may be defined as a plane in which the stress state becomes zero when bending, and the magnitude of tensile stress or compressive stress is determined in proportion to the distance from the neutral plane. Additionally, with respect to the Z direction, the neutral plane may be located at the center between the plane on which tensile stress acts and the plane on which compressive stress acts. Here, the surface on which compressive stress acts may be defined as a surface disposed close to the center of curvature, and the surface on which tensile stress acts may be defined as the surface opposite to the surface on which compressive stress acts.

In addition, cracks are more likely to occur in the light-emitting element layer 16 disposed in a region where tensile stress acts than in the light-emitting element layer 16 disposed in a region where compressive stress acts. Accordingly, because a region subject to tensile stress is more vulnerable to crack occurrence than a region subject to compressive stress during bending, even if the neutral plane is moved closer to the light-emitting element layer 16, the stress applied to the light-emitting element layer 16 may be minimized or at least reduced by moving the neutral plane so that the light-emitting element layer 16 is located at a position where compressive stress is applied.

Hence, the display device according to an embodiment of the present disclosure may regulate the thickness T1 of the substrate 10, the depths D1 and D2 of the buffer section 30A and auxiliary buffer section 40A formed in correspondence to the thickness T1 of the substrate 10, and the thickness T2 of the organic film 12 to move the position of the neutral plane to the light-emitting element layer 16 or closer to the light-emitting element layer 16. Accordingly, the stress acting on the light-emitting element layer 16 during bending may be reduced, so that it is possible to achieve improvement in terms of fold mark or hinge stain.

The substrate 10 is made of an insulating material or a material with flexibility, and may be formed to have a specific thickness T1. For example, the substrate 110 may be made of glass, metal, or plastic, but without being limited thereto. However, the substrate 10 may be a glass substrate having a specific strength for the etching process. Here, the substrate 10 may be made of plate-shaped alkali-free glass or non-alkali glass.

In addition, the substrate 10 may be disposed in the folding region FO and the non-folding region NFO. Hence, the substrate 10 may be divided into a folding region FO and a non-folding region NFO.

In addition, the substrate 10 includes a buffer section 30A and at least two auxiliary buffer sections 40A disposed to be spaced apart from the buffer section 30A. Here, the auxiliary buffer section 40A may be arranged to have a first separation distance SAD1 from the buffer section 30A. Also, the buffer section 30A may be referred to as a first buffer section, and the auxiliary buffer section 40A may be referred to as a first auxiliary buffer section.

The buffer section 30A may be disposed in the folding region FO. Here, the folding region FO where the buffer section 30A is disposed may be called a first folding region, the non-folding region NFO extended from one side of the folding region FO may be called a first non-folding region, and the non-folding region NFO extended from the other side of the folding region FO may be called a second non-folding region.

In addition, a portion of the auxiliary buffer section 40A may be disposed in the folding region FO, but without being limited thereto. For example, depending on the design criteria of the display device, the auxiliary buffer section 40A may be disposed only in the folding region FO or only in the non-folding region NFO. However, some region of the display panel 100 may include a bending region with a specific curvature, and the auxiliary buffer section 40A may be disposed in the bending region, thereby reducing stress caused by bending. Consequently, a part of the auxiliary buffer section 40A may be disposed in the folding region FO, and the remaining part thereof may be disposed in the non-folding region NFO.

The buffer section 30A and auxiliary buffer sections 40A may be provided as grooves concavely formed on the rear surface of the display panel 100 with respect to the display panel 100. In this case, with respect to the substrate 10, the auxiliary buffer sections 40A may be provided as a hole, and the auxiliary buffer sections 40A may be provided as a groove in consideration of the position of the neutral plane and rigidity for bending. Herein, the front surface of the display panel 100 may represent one surface of the display panel 100 on which an input image is reproduced, and the rear surface may represent a surface opposite to the front surface. Additionally, each component of the display panel 100 may also include a front surface and a rear surface. For example, the substrate 10 may include a front surface and a rear surface; the front surface of the substrate 10 may represent one surface of the substrate 10 disposed on the front side of the display panel 100, and the rear surface of the substrate 10 may represent a surface opposite to the front surface of the substrate 10.

The buffer section 30A may be provided as a groove having a specific first width W1 and first depth D1, and the auxiliary buffer section 40A may be provided as a hole having a specific second width W2 and second depth D2. Additionally, the auxiliary buffer section 40A may be disposed to have a specific separation distance SAD1 from the buffer section 30A in correspondence to the second bending region BA2. Here, the first width W1 and the first depth D1 of the buffer section 30A and the second width W2 and the second depth D2 of the auxiliary buffer section 40A may be regulated in consideration of the rigidity and degree of bending of the display panel 100. The first width W1 of the buffer section 30A may be formed to be greater than the second width W2 of the auxiliary buffer section 40A in correspondence to the first bending region BA1 having a relatively greater curvature than the second bending region BA2.

With respect to the rear surface of the substrate 10, the depth D1 of the buffer section 30A may be formed to be smaller than the depth D2 of the auxiliary buffer section 40A in correspondence to the first bending region BA1 having a relatively greater curvature than the second bending region BA2. As shown in FIG. 3, because a portion of the substrate 10 is disposed between the buffer section 30A and the organic film 12, this may respond more effectively to the first bending region BA1 having a relatively larger curvature than the second bending region BA2. Here, the depth D2 of the auxiliary buffer section 40A may be equal to the thickness T1 of the substrate 10, and the depth D1 of the buffer section 30A may be formed to be smaller than the thickness T1 of the substrate 10.

Meanwhile, the buffer section 30A provided as a groove and the auxiliary buffer section 40A provided as a hole may be formed through an etching process. For example, the substrate 10 may be etched by spraying an etchant on the substrate 10 to which a mask is bonded, or by a dipping method of immersing the substrate 10 in a water bath containing an etchant. At this time, the buffer section 30A provided as a groove and the auxiliary buffer section 40A provided as a hole can be formed through first etching using a mask and a laser. Then, the position of the neutral plane may be regulated by controlling the thickness of the substrate 10 through second etching after removing the mask.

Therefore, because the display device according to an embodiment of the present disclosure may form the buffer section 30A and the auxiliary buffer section 40A at the same time through an etching process, when manufacturing the display panel 100, process optimization, or at least improvement, is possible through process simplification. In addition, because the buffer section 30A and the plural auxiliary buffer sections 40A may be formed simultaneously through an etching process, the side surface 31 of the groove provided as the buffer section 30A and the side surface 41 of the hole provided as the auxiliary buffer section 40A may be formed to have a tapered surface.

The substrate 10 may be in contact with the organic film 12. When the organic film 12 is omitted, the substrate 10 may be in contact with the circuit layer 14. However, the display panel 100 may prevent damage to the circuit layer 14 and the light-emitting element layer 16 caused by the etching process through the organic film 12 additionally disposed between the substrate 10 and the circuit layer 14, and regulate the position of the neutral plane through the thickness T2 of the organic film 12. In this case, the thickness T2 of the organic film 12 is formed to be smaller than the thickness T1 of the substrate 10.

The organic film 12 may be a film containing one selected from the group consisting of polyimide-based polymer, polyester-based polymer, silicone-based polymer, acrylic polymer, polyolefin-based polymer, and copolymers thereof. Here, polyimide has acid resistance and heat resistance, so it may be applied to a high temperature process for the circuit layer 14 and the light-emitting element layer 16. Thereby, because the circuit layer 14 may be formed directly on the substrate 10, the organic film 120 may be omitted.

The organic film 12 may serve as an etch stopper in an etching process. For example, because the organic film 12 disposed between the substrate 10 and the circuit layer 14 covers the auxiliary buffer section 40A provided as a hole, the organic film 12 made of an organic material may prevent damage to the circuit layer 14 and the light-emitting element layer 16 due to an etching process. In this case, the organic film 12 may be formed to have a specific thickness T2, so that the position of the neutral plane may be regulated.

The circuit layer 14 may include data lines, pixel circuits connected to gate lines and power lines, and a gate driver connected to the gate lines. The pixel circuits and gate driver may include circuit elements, such as thin film transistors (TFT) and capacitors. To reduce the stress applied to the circuit layer 14 when the folding region FO is bent, the circuit layer 14 in the folding region FO may include only the wires, such as data lines, gate lines, and power lines.

The light-emitting element layer 16 may include an OLED driven by a driving element of a pixel circuit. The OLED includes an organic compound layer formed between the anode and the cathode. The organic compound layer may include, but not limited to, a hole injection layer (HIL), a hole transport layer (HTL), an emission layer (EML), an electron transport layer (ETL), and an electron injection layer (EIL). When a voltage is applied to the anode and the cathode of the OLED, holes passing through the hole transport layer (HTL) and electrons passing through the electron transport layer (ETL) are moved to the emission layer (EML) to form excitons, thereby emitting visible light in the emission layer (EML). The light-emitting element layer 16 may further include a color filter array that selectively transmits red, green, and blue wavelengths.

The light-emitting element layer 16 and the circuit layer 14 may be covered with a protective layer (not shown). The protective layer and encapsulation layer 18 may be composed of an inorganic film made of glass, metal, aluminum oxide (AlOx), or silicon (Si)-based material, or may have a structure in which an organic film and an inorganic film are alternately stacked. The inorganic film blocks the penetration of moisture or oxygen. The organic film planarizes the surface of the inorganic film. When the organic film and the inorganic film are stacked in multiple layers, the movement path of moisture or oxygen becomes longer compared to a single layer, so the penetration of moisture/oxygen affecting the light-emitting element layer 16 may be effectively blocked.

The polarizer 20 may be attached to the encapsulation layer 18 with an adhesive. The polarizer 20 improves the outdoor visibility of the display device. The polarizer 20 reduces light reflected from the surface of the display panel 100 and blocks light reflected from the metal of the circuit layer to thereby improve the brightness of pixels. The polarizer 20 may be implemented with a polarizer in which a linear polarizer and a phase retardation film are bonded, or a circular polarizer.

The cover glass 22 may be disposed on the polarizer 20 and may be made of a transparent material. For example, the cover glass 22 may be made of a glass material with a specific strength, but without being limited thereto.

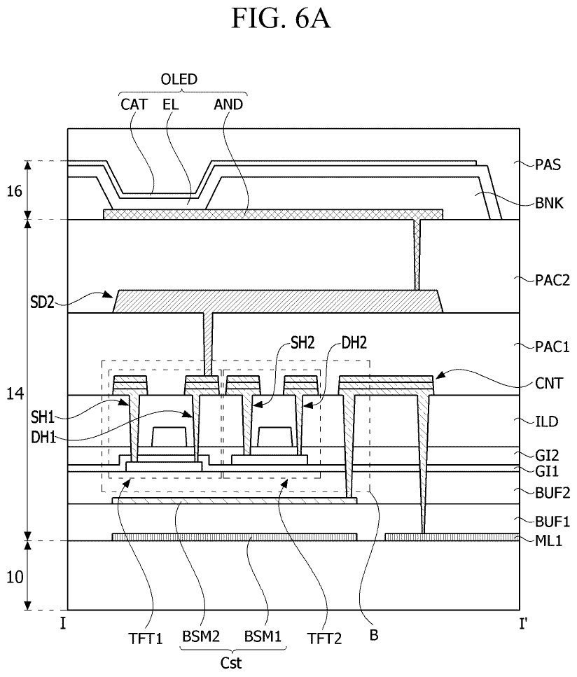

FIG. 6 is a cross-sectional view illustrating a pixel (Px) of the display panel according to an embodiment of the present disclosure; FIG. 6A is a cross-sectional view illustrating the substrate 10, circuit layer 14, and light-emitting element layer 16 of the display panel along line I-I′ in FIG. 2, and FIG. 6B is an enlarged view of region B in FIG. 6A.

With reference to FIG. 6, in the display area DA, a first transistor TFT1 and a second transistor TFT2 may be disposed on the substrate 10, and a light-emitting element OLED may be disposed on a planarization layer PAC2. A first light shield layer BSM1 and a first metal layer ML1 may be disposed on the substrate 10. The first light shield layer BSM1 may include molybdenum and/or aluminum. The first light shield layer BSM1 may block light incident to the first semiconductor layer ACT1 or the second semiconductor layer ACT2. Here, the first light shield layer BSM1 may overlap the first semiconductor layer ACT1 or the second semiconductor layer ACT2 in the Z direction.

The first metal layer ML1 may be disposed to be spaced apart from the first light shield layer BSM1 and may be formed together with the first light shield layer BSM1 in a process of forming the first light shield layer BSM1. Additionally, the first metal layer ML1 may be electrically connected to the pad part. The multi-buffer layer BUF1 may delay the diffusion of moisture or oxygen that has penetrated the substrate 110, and may be formed by alternately stacking silicon nitride (SiNx) and silicon oxide (SiOx) at least once.

A second light shield layer BSM2 may be disposed on the multi-buffer layer BUF1. The second light shield layer BSM2 may include molybdenum and/or aluminum. The second light shield layer BSM2 may block light incident to the first semiconductor layer ACT1 or the second semiconductor layer ACT2. The second light shield layer BSM2 may be disposed to overlap the first light shield layer BSM1 in the Z direction, more effectively blocking light incident to the first semiconductor layer ACT1 or the second semiconductor layer ACT2.

The active buffer layer BUF2 may protect the first semiconductor layer ACT1 and may serve to block various types of defects coming from the substrate 110. Here, the active buffer layer BUF2 may be made of a-Si, silicon nitride (SiNx), or silicon oxide (SiOx).

The first semiconductor layer ACT1 of the first transistor TFT1 may be made of a polycrystalline semiconductor layer, and the first semiconductor layer ACT1 may include a channel region, a source region, and a drain region.

A first gate electrode GE1 may be disposed on the upper gate insulating layer GI2 to overlap the first semiconductor layer ACT1. Here, the upper gate insulating layer GI2 may be disposed on a lower gate insulating layer GI1.

The second transistor TFT2 may be disposed on the lower gate insulating layer GI1. An upper gate insulating layer GI2 may be disposed on the second semiconductor layer ACT2 to insulate the second gate electrode GE2 from the second semiconductor layer ACT2.

An interlayer insulating layer ILD may be disposed on the first gate electrode GE1 and the second gate electrode GE2. The first gate electrode GE1 and the second gate electrode GE2 may be a single layer or a multilayer made of any one of molybdenum (Mo), aluminum (Al), chromium (Cr), gold (Au), titanium (Ti), nickel (Ni), neodymium (Nd), and copper (Cu), or an alloy thereof, but without being limited thereto.

After the interlayer insulating layer ILD is disposed, a first source contact hole SH1 and a first drain contact hole DH1 may be formed respectively in correspondence to the source region and drain region of the first transistor TFT1, and a second source contact hole SH2 and a second drain contact hole DH2 may be formed respectively in correspondence to the source region and drain region of the second transistor TFT2.

The first source contact hole SH1 and the first drain contact hole DH1 may be a hole formed continuously from the interlayer insulating layer ILD to the lower gate insulating layer GI1, and the second source contact hole SH2 and the second drain contact hole DH2 may also be formed continuously from the interlayer insulating layer ILD to the upper gate insulating layer GI2 in the second transistor TFT2.

The first source electrode E11 and the first drain electrode E12 corresponding to the first transistor TFT1, and the second source electrode E21 and the second drain electrode E22 corresponding to the second transistor TFT2 may be formed simultaneously. Thus, the number of processes for forming the source and drain electrodes of each of the first transistor TFT1 and the second transistor TFT2 may be reduced.

The first source and drain electrodes E11 and E12 and the second source and drain electrodes E21 and E22 may be a single layer or a multilayer made of any one of molybdenum (Mo), aluminum (Al), chromium (Cr), gold (Au), titanium (Ti), nickel (Ni), neodymium (Nd), and copper (Cu), or an alloy thereof, but without being limited thereto. The first source and drain electrodes E11 and E12 and the second source and drain electrodes E21 and E22 may be made of a three-layer structure; for example, the first source electrode E11 may be composed of a first layer Ella made of Ti, a second layer E11b made of A1, and a third layer Ellc made of Ti, and the other source and drain electrodes may have the same structure.

A storage capacitor Cst may be disposed between the first transistor TFT1 and the second transistor TFT2. According to an embodiment, the storage capacitor Cst may be formed using the first light shield layer BSM1 and second light shield layer BSM2. For example, the second light shield layer BSM2 may be electrically connected to the pixel circuit through a storage supply line CNT. However, the structure of the storage capacitor Cst is not necessarily limited to this and may be formed in various forms using two different metal layers.

The storage supply line CNT may be made of the same material as, on the same plane as, the first source and drain electrodes E11 and E12 and the second source and drain electrodes E21 and E22, and thus the storage supply line CNT may be formed simultaneously with the first source and drain electrodes E11 and E12 and the second source and drain electrodes E21 and E22 using the same mask process. A first planarization layer PAC1 may be formed on the first source and drain electrodes E11 and E12, the second source and drain electrodes E21 and E22, and the storage supply line CNT. Specifically, the first planarization layer PAC1 may be disposed by applying a full coating of an organic insulating material, such as acrylic resin on the first source and drain electrodes E11 and E12, the second source and drain electrodes E21 and E22, and the storage supply line CNT.

After disposing the first planarization layer PAC1, a contact hole may be formed through a photolithography process to expose the first source electrode E11 or first drain electrode E12 of the first transistor TFT1. A connection electrode SD2 may be disposed in the contact hole region exposing the first drain electrode E12 using a material made of Mo, Ti, Cu, AlNd, Al, Cr, or an alloy thereof.

A second planarization layer PAC2 may be disposed on the connection electrode SD2. Then, a contact hole exposing the connection electrode SD2 may be formed in the second planarization layer PAC2 to dispose a light-emitting element OLED connected to the first transistor TFT1. The connection electrode SD2 may be formed with a plurality of layer structures in a manner identical to the first source and drain electrodes E11 and E12.

The light-emitting element OLED may include an anode electrode AND connected to the first drain electrode E12 of the first transistor TFT1, at least one light-emitting stack EL formed on the anode electrode AND, and a cathode electrode CAT formed on the light-emitting stack EL. The light-emitting stack EL may include a hole injection layer, a hole transport layer, an emission layer, an electron transport layer, and an electron injection layer; in a tandem structure where a plurality of emission layers overlap, a charge generation layer may be additionally disposed between the emission layers. In the case of the emission layer, there may be cases where individual sub-pixels emit different colors.

The anode electrode AND may be connected to the connection electrode SD2 exposed through a contact hole penetrating the second planarization layer PAC2. The anode electrode AND may be formed in a multi-layer structure including a transparent conductive film and an opaque conductive film with high reflection efficiency. The transparent conductive film may be made of a material with a relatively high work function value, such as indium-tin-oxide (ITO) or indium-zinc-oxide (IZO), and the opaque conductive film may be formed in a single-layer or multi-layer structure containing Al, Ag, Cu, Pb, Mo, Ti, or an alloy thereof.

For example, the anode electrode AND may be formed in a structure where a transparent conductive film, an opaque conductive film, and a transparent conductive film are stacked in sequence, or may be formed in a three-layer structure like the first source and drain electrodes E11 and E12. The anode electrode AND may be disposed on the second planarization layer PAC2 to overlap not only the emission area provided by the bank BNK but also the pixel circuit area where the first and second transistors TFT1 and TFT2 and the storage capacitor Cst are arranged, increasing the area of emission.

The light-emitting stack EL may be formed by stacking a hole transport layer, an organic emission layer, and an electron transport layer in that order or in the reverse order on the anode electrode AND. In addition, the light-emitting stack EL may further include a charge generation layer, and include first and second light-emitting stacks facing each other with a charge generation layer interposed therebetween.

The bank BNK may be formed to expose the anode electrode AND. This bank BNK may be made of an organic material, such as photo acryl, and may be a translucent material, but without being limited thereto. For example, the bank BNK may be made of an opaque material to prevent light interference between sub-pixels.

The cathode electrode CAT may be formed on the upper surface of the light-emitting stack EL to face the anode electrode AND with the light-emitting stack EL interposed therebetween. When applied to an organic light-emitting display device of a front-emitting type, the cathode electrode CAT may be provided as a transparent conductive film made of thinned indium-tin-oxide (ITO), indium-zinc-oxide (IZO), or magnesium-silver (Mg—Ag).

An encapsulation portion PAS may be formed on the cathode electrode CAT to protect the light-emitting element OLED. In the light-emitting element OLED, owing to the organic nature of the light-emitting stack EL, a dark spot or pixel shrinkage may occur due to reaction with external moisture or oxygen. To prevent this, the encapsulation portion PAS may be disposed on the cathode electrode CAT.

The encapsulation portion PAS may represent a part of the encapsulation layer 18, and may be composed of a first inorganic insulating layer, a foreign material compensation layer, and a second inorganic insulating layer. The polarizer 20 and the cover glass 22 may be further disposed on the upper portion forming the encapsulation portion PAS, but without being limited thereto.

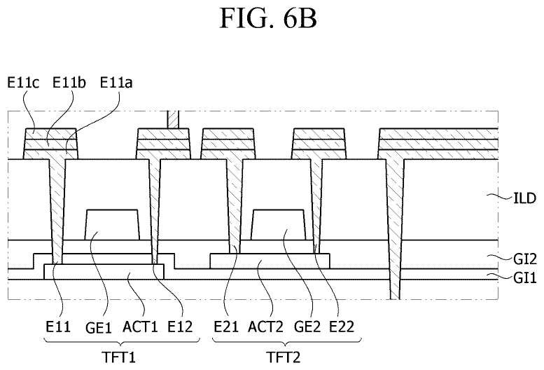

FIG. 7 is a view showing another example of the display panel disposed in a display device according to an embodiment of the present disclosure.

With reference to FIG. 7, the display panel 100 according to the first embodiment may further include a touch sensor layer 19. The touch sensor layer 19 may be disposed between the encapsulation layer 18 and the polarizer 20, and may be formed to have a specific thickness. Touch sensors and touch sensor wires may be formed in the touch sensor layer 19, and the touch sensor wires may connect the touch sensors to a touch sensor driver. Additionally, the touch sensor layer 19 may include insulating films that insulate the intersecting portions of the metal wire patterns and planarize the surface of the touch sensor layer.

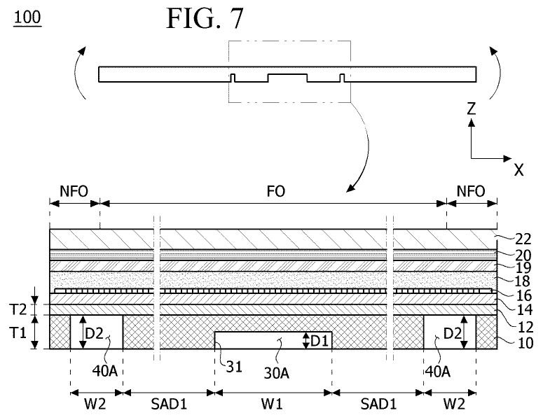

FIG. 8 is a view showing another example of the display panel disposed in a display device according to an embodiment of the present disclosure. The display panel 100 shown in FIG. 8 may represent a display panel according to the second embodiment.

When comparing the display panel 100 according to the first embodiment and the display panel 100 according to the second embodiment with reference to FIG. 3 and FIG. 8, the display panel 100 according to the second embodiment differs from the display panel 100 according to the first embodiment in that a filler 50 is further disposed inside the buffer section 30A.

With reference to FIG. 8, the display panel 100 according to the second embodiment may include a substrate 10, an organic film 12 disposed on the substrate 10, a circuit layer 14 disposed on the organic film 12, a light-emitting element layer 16 disposed on the circuit layer 14, an encapsulation layer 18 covering the circuit layer 14 and the light-emitting element layer 16, a polarizer 20 disposed on the encapsulation layer 18, a cover glass 22 disposed on the polarizer 20, and a filler 50 disposed in the buffer section 30A of the substrate 10. Additionally, the display panel 100 according to the second embodiment may further include the touch sensor layer 19 shown in FIG. 7. Here, the touch sensor layer 19 may be disposed between the encapsulation layer 18 and the polarizer 20.

The filler 50 may be disposed inside the buffer section 30A provided as a groove. In this case, because the curvature 1/R1 of the first bending region BA1 is greater than the curvature 1/R2 of the second bending region BA2, a filler 50 may be not disposed in the auxiliary buffer section 40A. The filler 50 may include a resin material with good elasticity and may be made of an organic material. For example, the filler 50 may be a polymer that may be cured by heat or UV irradiation and may be selected from acrylic resin, urethane resin, silicone resin, and the like, but without being limited thereto. Accordingly, the filler 50 may reduce the strain of the display panel 100 by reinforcing the rigidity of the display panel 100, thereby preventing fold marks or hinge stains from appearing.

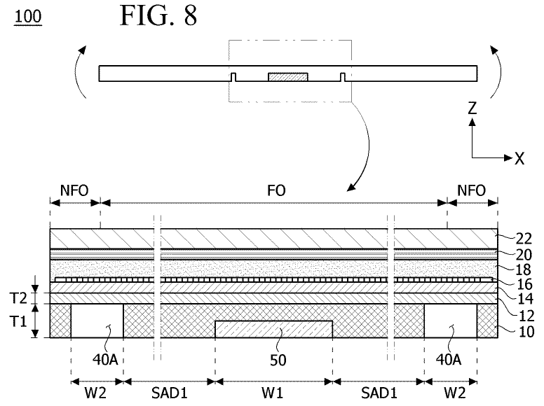

FIG. 9 is a view showing another example of the display panel disposed in a display device according to an embodiment of the present disclosure. The display panel 100 shown in FIG. 9 may represent a display panel according to the third embodiment.

When comparing the display panel 100 according to the first embodiment and the display panel 100 according to the third embodiment with reference to FIG. 3 and FIG. 9, the display panel 100 according to the third embodiment differs from the display panel 100 according to the first embodiment in that it further includes a mid-frame disposed under the substrate 10. Hence, air may be disposed in the buffer section 30A of the substrate 10, and the buffer section 30A may be provided as an air gap of the display panel 100.

With reference to FIG. 9, the display panel 100 according to the third embodiment may include a substrate 10, an organic film 12 disposed on the substrate 10, a circuit layer 14 disposed on the organic film 12, a light-emitting element layer 16 disposed on the circuit layer 14, an encapsulation layer 18 covering the circuit layer 14 and the light-emitting element layer 16, a polarizer 20 disposed on the encapsulation layer 18, a cover glass 22 disposed on the polarizer 20, and a mid-frame 60 disposed on the rear surface of the substrate 10. Additionally, the display panel 100 according to the third embodiment may further include the touch sensor layer 19 shown in FIG. 7. Here, the touch sensor layer 19 may be disposed between the encapsulation layer 18 and the polarizer 20.

The mid-frame 60 may be disposed on the rear surface of the substrate 10 to support the substrate 10. At this time, the mid-frame 60 may be attached to the rear surface of the substrate 10 using an adhesive and may cover the buffer section 30A and auxiliary buffer sections 40A formed on the substrate 10. Accordingly, the mid-frame 60 may reduce the strain of the display panel 100 by reinforcing the rigidity of the display panel 100, thereby preventing fold marks or hinge stains from appearing.

The mid-frame 60 may be formed in a plate shape with a specific thickness and may be made of a material with rigidity. For example, the mid frame 60 may be made of a metal material, such as SUS (Steel Use Stainless) or Invar, or a rigid material, such as plastic. Hence, the mid-frame 60 may improve the rigidity of the display panel 100 while regulating the position of the neutral plane. In this case, the mid-frame 60 is formed to have a specific thickness smaller than the thickness T1 of the substrate 10.

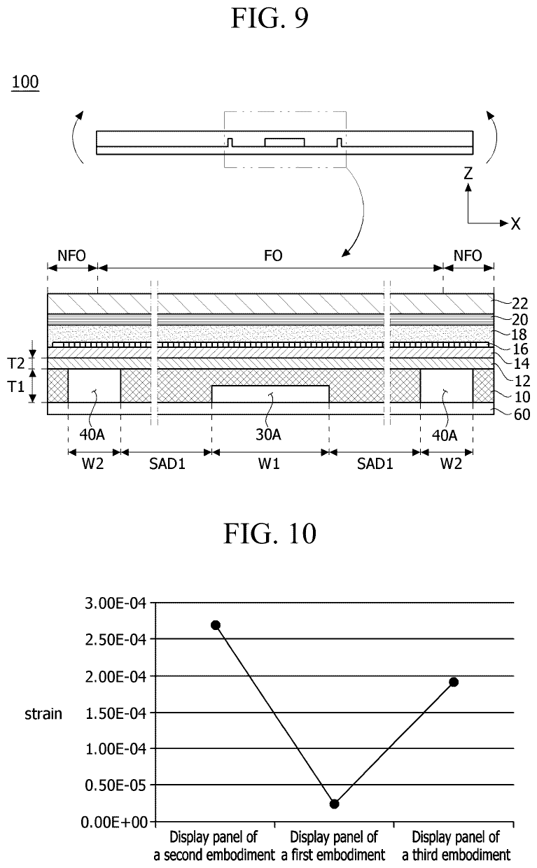

FIG. 10 is a graph showing the degree of deformation in the folding region according to the embodiments of the display panel, and may indicate the strain of the display panel 100 according to the first to third embodiments. Specifically, FIG. 10 may indicate the strain in the first bending region BA1 of the display panel 100 according to the first to third embodiments.

With reference to FIG. 10, the strain of the display panel 100 according to the first embodiment is relatively smaller than the strain of the display panel 100 according to the third embodiment. Also, the strain of the display panel 100 according to the third embodiment is relatively smaller than the strain of the display panel 100 according to the second embodiment.

Accordingly, the display device according to the present disclosure may utilize one of the display panels 100 according to the first to third embodiments in consideration of design criteria, such as the rigidity of the display panel 100 and strain due to folding.

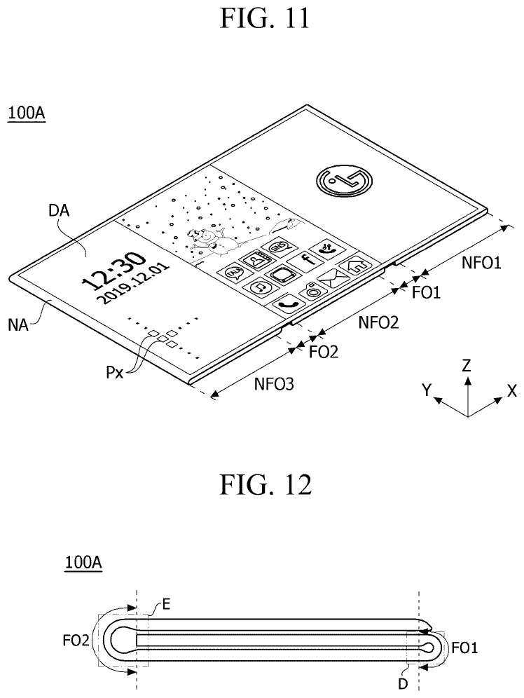

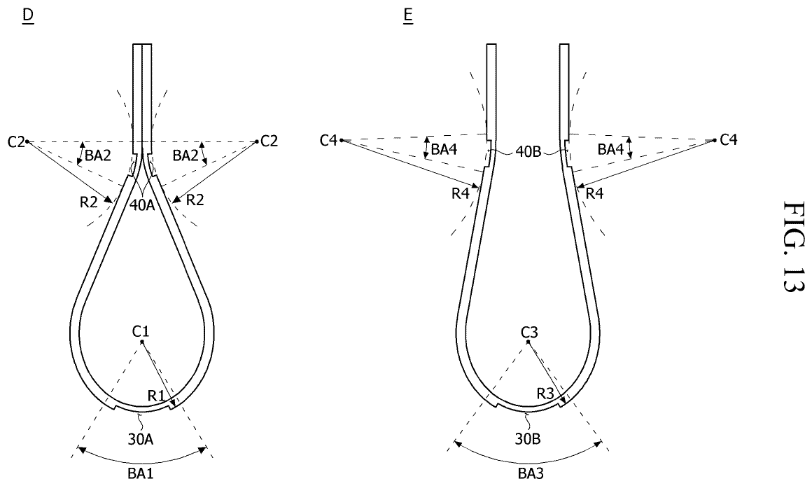

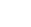

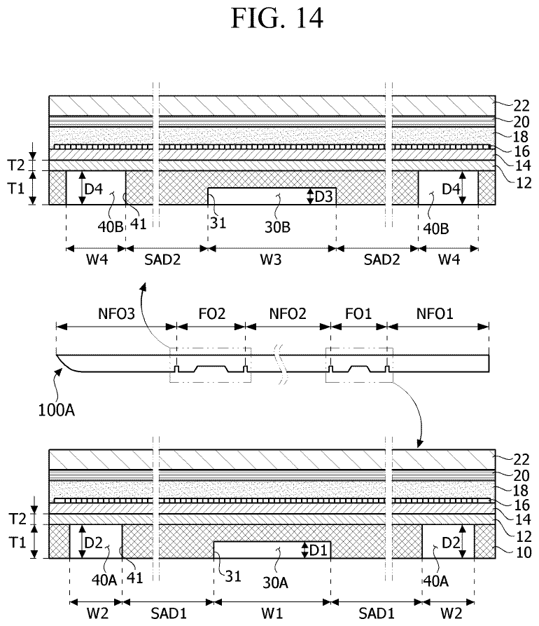

FIG. 11 is a perspective view illustrating the display panel of a display device according to another embodiment of the present disclosure, FIG. 12 is a view illustrating the folded state of the display panel disposed in a display device according to another embodiment of the present disclosure, FIG. 13 is an enlarged view of regions D and E in FIG. 12, and FIG. 14 is a front view illustrating the display panel disposed in a display device according to another embodiment of the present disclosure. Here, the display panel 100A shown in FIGS. 11 to 14 may represent a display panel according to the fourth embodiment. Additionally, the enlarged view of the folding region in FIG. 13 may be a conceptual diagram showing a folded state.

When comparing the display panel 100 shown in FIG. 2 and the display panel 100A shown in FIG. 11, the display panel 100A shown in FIG. 11 differs from the display panel 100 shown in FIG. 2 in that it includes at least two folding regions FO1 and FO2 so that it may be used in a multi-folding display.

With reference to FIGS. 11 to 14, the display panel 100A according to the fourth embodiment may include a substrate 10, an organic film 12 disposed on the substrate 10, a circuit layer 14 disposed on the organic film 12, a light-emitting element layer 16 disposed on the circuit layer 14, an encapsulation layer 18 covering the circuit layer 14 and the light-emitting element layer 16, a polarizer 20 disposed on the encapsulation layer 18, and a cover glass 22 disposed on the polarizer 20. Additionally, the display panel 100A according to the fourth embodiment may include two buffer sections 30A and 30B being spaced apart from each other, and four auxiliary buffer sections 40A and 40B.

In addition, the display panel 100A according to the fourth embodiment may include two folding regions FO1 and FO2, and three non-folding regions NFO1, NFO2 and NFO3. Here, the two buffer sections 30A and 30B may be disposed respectively in the two folding regions FO1 and FO2. For example, the display panel 100A may include a first non-folding region NFO1, a second non-folding region NFO2, a third non-folding region NFO3, which are disposed to be spaced apart from each other, a first folding region FO1 disposed between the first non-folding region NFO1 and the second non-folding region NFO2, and a second folding region FO2 disposed between the second non-folding region NFO2 and the third non-folding region NFO3. In addition, the substrate 10 may include a first buffer section 30A disposed in the first non-folding region NFO1, a second buffer section 30B disposed in the second non-folding region NFO2, at least two first auxiliary buffer sections 40A disposed to be spaced apart from the first buffer section 30A with the first buffer section 30A interposed therebetween, and at least two second auxiliary buffer sections 40B disposed to be spaced apart from the second buffer section 30B with the second buffer section 30B interposed therebetween.

As the display panel 100A is folded in the two folding regions FO1 and FO2, the first non-folding region NFO1, the second non-folding region NFO2, and the third non-folding region NFO3 may be disposed to overlap. In this case, the first non-folding region NFO1 may be arranged between the second non-folding region NFO2 and the third non-folding region NFO3, but without being limited thereto.

The folded display panel 100A may include a plurality of bending regions with different bending degrees. As shown in FIG. 12, the folded display panel 100A may include a first bending region BA1, two second bending regions BA2, a third bending region BA3, and two fourth bending regions BA4, which have different curvatures. Additionally, the second bending regions BA2 are arranged to be spaced apart from the first bending region BA1, and the fourth bending regions BA4 are arranged to be spaced apart from the third bending region BA3.

The first bending region BA1 is a region of the display panel 100A where the first buffer section 30A is disposed, and may be formed to have a first curvature 1/R1 with respect to the virtual center of curvature C1. In addition, the second bending region BA2 is a region of the display panel 100A where the first auxiliary buffer section 40A is disposed, and may be formed to have a second curvature 1/R2 with respect to the virtual center of curvature C2. In addition, the third bending region BA3 is a region of the display panel 100A where the second buffer section 30B is disposed, and may be formed to have a third curvature 1/R3 with respect to the virtual center of curvature C3. In addition, the fourth bending region BA4 is a region of the display panel 100A where the second auxiliary buffer section 40B is disposed, and may be formed to have a fourth curvature 1/R4 with respect to the virtual center of curvature C4. Here, the radius of curvature R1 of the first bending region BA1, the radius of curvature R2 of the second bending region BA2, the radius of curvature R3 of the third bending region BA3, and the radius of curvature R4 of the fourth bending region BA4 may respectively be the distances from the virtual centers of curvature C1, C2, C3 and C4 to the rear surface of the bent substrate 10.

The center of curvature C1 of the first bending region BA1 is disposed to be closer to the cover glass 22 than the substrate 10, and the center of curvature C2 of the second bending region BA2 is disposed to be closer to the substrate 10 than the cover glass 22. In addition, the center of curvature C3 of the third bending region BA3 is disposed to be closer to the cover glass 22 than the substrate 10, and the center of curvature C4 of the fourth bending region BA4 is disposed to be closer to the substrate 10 than the cover glass 22. For example, with respect to the folded display panel 100A, the center of curvature C1 of the first bending region BA1 and the center of curvature C3 of the third bending region BA3 are disposed on the inside, and the center of curvature C2 of the second bending region BA2 and the center of curvature C4 of the fourth bending region BA4 may be disposed on the outside adjacent to the case 200.

Because the curvature 1/R1 of the first bending region BA1 is greater than the curvature 1/R2 of the second bending region BA2, the display panel 100A forms a relatively gentler curve in the second bending region BA2 than in the first bending region BA1. In addition, because the curvature 1/R3 of the third bending region BA3 is greater than the curvature 1/R4 of the fourth bending region BA4, the display panel 100A forms a relatively gentler curve in the fourth bending region BA4 than in the third bending region BA3. In this case, the radius of curvature R3 of the third bending region BA3 may be greater than the radius of curvature R1 of the first bending region BA1 and less than the radius of curvature R2 of the second bending region BA2. In addition, the radius of curvature R4 of the fourth bending region BA4 may be greater than the radius of curvature R3 of the third bending region BA3. As a result, the degrees of bending in the individual bending regions BA1, BA2, BA3, BA4 are different, so that the positions of the neutral plane in the individual bending regions BA1, BA2, BA3, BA4 may be different and the stress applied to the bending regions BA1 and BA2 may be different.

The first buffer section 30A may be disposed in the first folding region FO1. Additionally, the first buffer section 30A may be provided as a groove formed concavely on the rear surface of the display panel 100A with respect to the display panel 100A. Additionally, the first buffer section 30A may be formed to have a specific first width W1 and first depth D1, and the first width W1 and first depth D1 of the first buffer section 30A may be regulated in consideration of the rigidity and bending degree of the display panel 100A. In this case, the first width W1 of the first buffer section 30A is formed to be larger than the second width W2 of the first auxiliary buffer section 40A, and the first depth D1 of the first buffer section 30A may be formed to be smaller than the second depth D2 of the first auxiliary buffer section 40A.

The at least two first auxiliary buffer sections 40A may be disposed to be spaced apart from the first buffer section 30A, and the first buffer section 30A may be disposed between the at least two first auxiliary buffer sections 40A. In this case, the two first auxiliary buffer sections 40A may each be disposed to be spaced apart by a first separation distance SAD1 from the first buffer part 30A. In addition, a portion of one of the two first auxiliary buffer sections 40A may be disposed in the first folding region FO1, and the remaining portion thereof may be disposed in the first non-folding region NFO1. Also, a portion of the other of the two first auxiliary buffer sections 40A may be disposed in the first folding region FO1, and the remaining portion thereof may be disposed in the second non-folding region NFO2.

Additionally, the first auxiliary buffer section 40A may be provided as a groove concavely formed on the rear surface of the display panel 100A with respect to the display panel 100A. Additionally, the first auxiliary buffer section 40A may be formed to have a specific second width W2 and second depth D2, and the second width W2 and second depth D2 of the first auxiliary buffer section 40A may be regulated in consideration of the rigidity and bending degree of the display panel 100A.

The second buffer section 30B may be disposed in the second folding region FO2. Additionally, the second buffer section 30B may be provided as a groove concavely formed on the rear surface of the display panel 100A with respect to the display panel 100A. Additionally, the second buffer section 30B may be formed to have a specific third width W3 and third depth D3, and the third width W3 and third depth D3 of the second buffer section 30B may be regulated in consideration of the rigidity and bending degree of the display panel 100A.

The third width W3 of the second buffer section 30B may be formed to be larger than the fourth width W4 of the second auxiliary buffer section 40B, and the third depth D3 of the second buffer section 30B may be formed to be smaller than the fourth depth D4 of the second auxiliary buffer section 40B. In addition, because the curvature in the first bending region BA1 is greater than the curvature in the third bending region BA3, the third width W3 of the second buffer section 30B may be formed to be larger than the first width W1 of the first buffer section 30A.

In addition, the third depth D3 of the second buffer section 30B may be the same as the first depth D1 of the first buffer section 30A, but without being limited thereto. For example, as the curvature in the first bending region BA1 and the curvature in the third bending region BA3 are different, the third depth D3 of the second buffer section 30B may be different from the first depth D1 of the first buffer section 30A. Specifically, as the curvature in the first bending region BA1 is greater than the curvature in the third bending region BA3, the third depth D3 of the second buffer section 30B may be formed to be smaller than the first depth D1 of the first buffer section 30A.

The at least two second auxiliary buffer sections 40B may be arranged to be spaced apart from the second buffer section 30B, and the second buffer section 30B may be disposed between the at least two second auxiliary buffer sections 40B. In this case, the two second auxiliary buffer sections 40B may each be disposed to be spaced apart by a second separation distance SAD2 from the second buffer part 30B. Here, the second separation distance SAD2 is formed to be larger than the first separation distance SAD1.

Additionally, a portion of one of the two second auxiliary buffer sections 40B may be disposed in the second folding region FO2, and the remaining portion thereof may be disposed in the second non-folding region NFO2. Also, a portion of the other of the two second auxiliary buffer sections 40B may be disposed in the second folding region FO2, and the remaining portion thereof may be disposed in the third non-folding region NFO3.

Additionally, the second auxiliary buffer section 40B may be provided as a groove formed concavely on the rear surface of the display panel 100A with respect to the display panel 100A. Additionally, the second auxiliary buffer section 40B may be formed to have a specific fourth width W4 and fourth depth D4, and the fourth width W4 and fourth depth D4 of the second auxiliary buffer section 40B may be regulated in consideration of the rigidity and bending degree of the display panel 100A.

The fourth width W4 of the second auxiliary buffer section 40B may be formed to be larger than the second width W2 of the first auxiliary buffer section 40A. Additionally, the fourth depth D4 of the second auxiliary buffer section 40B may be the same as the second depth D2 of the first auxiliary buffer section 40A, but without being limited thereto. For example, as the curvature in the second bending region BA2 is different from the curvature in the fourth bending region BA4, the fourth depth D4 of the second auxiliary buffer section 40B may be different from the second depth D2 of the first auxiliary buffer section 40A. Specifically, as the curvature in the second bending region BA2 is greater than the curvature in the fourth bending region BA4, the fourth depth D4 of the second auxiliary buffer section 40B may be formed to be smaller than the second depth D2 of the first auxiliary buffer section 40A. Additionally, the first buffer section 30A, the second buffer section 30B, the first auxiliary buffer section 40A, and the second auxiliary buffer section 40B may be formed through an etching process.

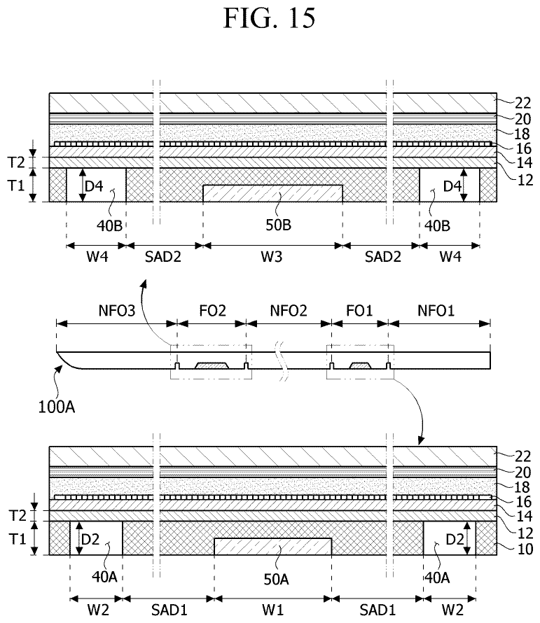

FIG. 15 is a view showing another example of the display panel disposed in a display device according to another embodiment of the present disclosure. The display panel 100 shown in FIG. 15 may represent a display panel according to a fifth embodiment.

With reference to FIG. 15, the display panel 100A according to the fifth embodiment may include a substrate 10 that includes two buffer sections 30A and 30B arranged to be spaced apart from each other and four auxiliary buffer sections 40A and 40B, an organic film 12 disposed on the substrate 10, a circuit layer 14 disposed on the organic film 12, a light-emitting element layer 16 disposed on the circuit layer 14, an encapsulation layer 18 covering the circuit layer 14 and the light-emitting element layer 16, a polarizer 20 disposed on the encapsulation layer 18, a cover glass 22 disposed on the polarizer 20, a first filler 50A disposed in the first buffer section 30A of the substrate 10, and a second filler 50B disposed in the second buffer section 30B of the substrate 10. Additionally, the display panel 100A according to the fifth embodiment may further include the touch sensor layer 19 shown in FIG. 7. Here, the touch sensor layer 19 may be disposed between the encapsulation layer 18 and the polarizer 20.

The first filler 50A may be disposed inside the first buffer section 30A provided as a groove, and the second filler 50B may be disposed inside the second buffer section 30B provided as a groove. The first filler 50A and the second filler 50B may include a resin material with good elasticity and may be made of an organic material.

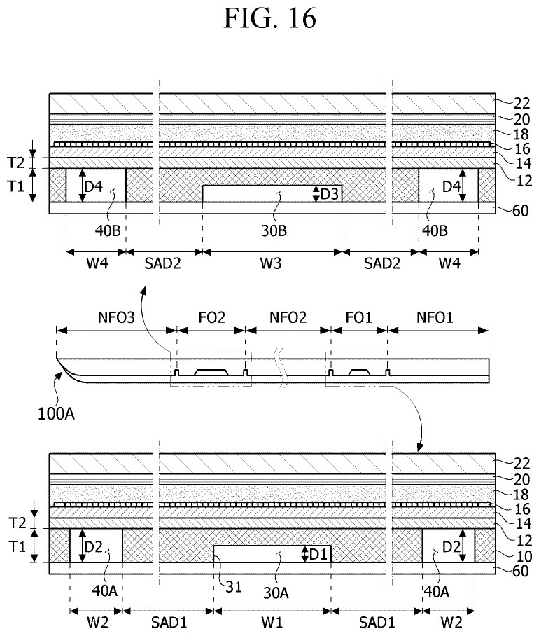

FIG. 16 is a view showing another example of the display panel disposed in a display device according to another embodiment of the present disclosure. The display panel 100 shown in FIG. 16 may represent a display panel according to a sixth embodiment.

With reference to FIG. 16, the display panel 100A according to the sixth embodiment may include a substrate 10 that includes two buffer sections 30A and 30B arranged to be spaced apart from each other and four auxiliary buffer sections 40A and 40B, an organic film 12 disposed on the substrate 10, a circuit layer 14 disposed on the organic film 12, a light-emitting element layer 16 disposed on the circuit layer 14, an encapsulation layer 18 covering the circuit layer 14 and the light-emitting element layer 16, a polarizer 20 disposed on the encapsulation layer 18, a cover glass 22 disposed on the polarizer 20, and a mid-frame 60 disposed on the rear surface of the substrate 10. Additionally, the display panel 100A according to the sixth embodiment may further include the touch sensor layer 19 shown in FIG. 7. Here, the touch sensor layer 19 may be disposed between the encapsulation layer 18 and the polarizer 20.

The mid-frame 60 may be disposed on the rear surface of the substrate 10 to support the substrate 10. In this case, the mid-frame 60 may be attached to the rear surface of the substrate 10 using an adhesive to cover the first buffer section 30A, the second buffer section 30B, the first auxiliary buffer section 40A, and the second auxiliary buffer section 40B, which are formed on the substrate 10. Accordingly, the mid frame 60 may reinforce the rigidity of the display panel 100, thereby reducing strain on the display panel 100.

The mid frame 60 may be formed in a plate shape with a specific thickness and may be made of a material with rigidity. At this time, the specific thickness of the mid frame 60 is formed to be smaller than the thickness T1 of the substrate 10.

The display device according to one or more embodiment of the present disclosure will be described as follows.

A display device according to one or more embodiment of the present disclosure may include a folding region and a plurality of non-folding regions. The display panel may include: a substrate; a circuit layer on the substrate to drive pixels; a light-emitting element layer on the circuit layer; an encapsulation layer covering the circuit layer and the light-emitting element layer; and a cover glass on the encapsulation layer, wherein the substrate includes a buffer section in the folding region, and at least two auxiliary buffer sections spaced apart from the buffer section with the buffer section interposed between the at least two auxiliary buffer sections.

The thickness of the substrate at the buffer section may be less than a thickness of the substrate at other portions.

The buffer section may include a groove defined concavely on a rear surface of the substrate, and the at least two auxiliary buffer sections may each include a hole penetrating the substrate.

The display panel may further comprise an organic filler in at least one of the groove and the hole.

The display panel may further include a mid-frame on the rear surface of the substrate.

The display panel may further include an organic film between the substrate and the circuit layer, wherein the substrate may include a glass material, and the organic film covers the hole of each auxiliary buffer section.

A thickness of the organic film may be less than a thickness the substrate.

A width of the buffer section may greater than a width of one of the at least two auxiliary buffer sections.

A depth of the buffer section may be less than a dept of the at least two auxiliary buffer sections with respect to the rear surface of the substrate.

The substrate may include a first bending region at a portion having the buffer section, and a second bending region spaced apart from the first bending region, and a curvature of the first bending region may greater than a curvature of the second bending region in a folded state of the display device.

The auxiliary buffer section may be in the second bending region.

The width of the buffer section may be greater than the width of the auxiliary buffer section, and the depth of the buffer section may be less than the depth of the auxiliary buffer section.

A display device according to one or more embodiment of the present disclosure may include at least two folding regions and a plurality non-folding regions. The display device may comprise a substrate; a circuit layer on the substrate to drive pixels; a light-emitting element layer on the circuit layer; an encapsulation layer covering the circuit layer and the light-emitting element layer; and a cover glass on the encapsulation layer, wherein the non-folding regions may include a first non-folding region, a second non-folding region, and a third non-folding region, wherein the folding regions may include a first folding region between the first non-folding region and the second non-folding region, and a second folding region between the second non-folding region and the third non-folding region, and wherein the substrate may include a first buffer section in the first folding region, a second buffer section in the second folding region, at least two first auxiliary buffer sections spaced apart from the first buffer section with the first buffer section interposed between the at least two first auxiliary buffer sections, and at least two second auxiliary buffer sections spaced apart from the second buffer section with the second buffer section interposed between the at least two first auxiliary buffer sections.

The thickness of the substrate at each of the first buffer section and the second buffer section may be less than a thickness of the substrate at other portions.

The first buffer section and the second buffer section may respectively include grooves defined concavely on a rear surface of the substrate, and the at least two first auxiliary buffer sections and the at least two second auxiliary buffer sections may respectively include holes penetrating the substrate.

The display device may further comprise organic fillers respectively in at least one of the grooves and the holes.

The display device may further include a mid-frame on the rear surface of the substrate.

The display device may further comprise an organic film between the substrate and the circuit layer, wherein the substrate may include a glass material, and the organic film may cover the holes.

A width of the second buffer section may be greater than a width of the first buffer section.

A depth of the first buffer section may be less than a depth of the at least two first auxiliary buffer sections, and a depth of the second buffer section may be less than a depth of the at least two second auxiliary buffer sections.

A depth of the second buffer section may be different than a depth of the first buffer section.

The substrate may include a first bending region at a portion having the first buffer section, a second bending region at a portion having the first auxiliary buffer section, a third bending region at a portion having the second buffer section, and a fourth bending region at a portion having the at least two the second auxiliary buffer section, wherein a curvature of the first bending region may be greater than a curvature of the third bending region in a folded state of the display device.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

### DESCRIPTION OF REFERENCE NUMERALS

100: Display Panel 10: Substrate
12: Organic film 14: Circuit layer
16: Light-emitting element layer 18: Encapsulation layer
19: Touch sensor layer 20: Polarizer
22: Cover glass 30: Buffer section
40: Auxiliary buffer section 50: Filler
60: Mid-frame

What is claimed is:

1. A display device comprising a folding region and a plurality of non-folding regions, the display device comprising:
a substrate;
a circuit layer on the substrate to drive pixels;
a light-emitting element layer on the circuit layer;
an encapsulation layer covering the circuit layer and the light-emitting element layer; and
a cover glass on the encapsulation layer,
wherein the substrate includes a buffer section in the folding region, and at least two auxiliary buffer sections spaced apart from the buffer section with the buffer section interposed between the at least two auxiliary buffer sections.

2. The display device of claim 1, wherein a thickness of the substrate at the buffer section is less than a thickness of the substrate at other portions.

3. The display device of claim 1, wherein the buffer section includes a groove defined concavely on a rear surface of the substrate; and
wherein the at least two auxiliary buffer sections each includes a hole penetrating the substrate.

4. The display device of claim 3, further comprising an organic filler in at least one of the groove and the hole.

5. The display device of claim 3, further comprising a mid-frame on the rear surface of the substrate.

6. The display device of claim 3, further comprising an organic film between the substrate and the circuit layer, wherein the substrate includes a glass material, and the organic film covers the hole of each auxiliary buffer section.

7. The display device of claim 6, wherein a thickness of the organic film is less than a thickness of the substrate.

8. The display device of claim 1, wherein a width of the buffer section is greater than a width of one of the at least two auxiliary buffer sections.

9. The display device of claim 1, wherein a depth of the buffer section is less than a depth of the at least two auxiliary buffer sections with respect to a rear surface of the substrate.

10. The display device of claim 1, wherein the substrate includes a first bending region at a portion having the buffer section, and a second bending region spaced apart from the first bending region; and
a curvature of the first bending region is greater than a curvature of the second bending region in a folded state of the display device.

11. The display device of claim 10, wherein the auxiliary buffer sections are in the second bending region.

12. The display device of claim 11, wherein a width of the buffer section is greater than a width of the auxiliary buffer section; and
wherein a depth of the buffer section is less than a depth of the auxiliary buffer sections.

13. A display device comprising at least two folding regions and a plurality of non-folding regions, the display device comprising:
a substrate;
a circuit layer on the substrate to drive pixels;
a light-emitting element layer on the circuit layer;
an encapsulation layer covering the circuit layer and the light-emitting element layer; and
a cover glass on the encapsulation layer,
wherein the non-folding regions include a first non-folding region, a second non-folding region, and a third non-folding region,
wherein the folding regions include a first folding region between the first non-folding region and the second non-folding region, and a second folding region between the second non-folding region and the third non-folding region, and
wherein the substrate includes a first buffer section in the first folding region, a second buffer section in the second folding region, at least two first auxiliary buffer sections spaced apart from the first buffer section with the first buffer section interposed between the at least two first auxiliary buffer sections, and at least two second auxiliary buffer sections apart from the second buffer section with the second buffer section interposed between the at least two first auxiliary buffer sections.

14. The display device of claim 13, wherein a thickness of the substrate at each of the first buffer section and the second buffer section is less than a thickness of the substrate at other portions.

15. The display device of claim 13, wherein the first buffer section and the second buffer section respectively include grooves defined concavely on a rear surface of the substrate; and
wherein the at least two first auxiliary buffer sections and the at least two second auxiliary buffer sections respectively include holes penetrating the substrate.

16. The display device of claim 15, further comprising organic fillers respectively in at least one of the grooves and the holes.

17. The display device of claim 15, further comprising a mid-frame on the rear surface of the substrate.

18. The display device of claim 15, further comprising an organic film between the substrate and the circuit layer, wherein the substrate includes a glass material, and the organic film covers the holes.

19. The display device of claim 13, wherein a width of the second buffer section is greater than a width of the first buffer section.

20. The display device of claim 13, wherein a depth of the first buffer section is less than a depth of the at least two first auxiliary buffer sections; and
a depth of the second buffer section is less than a depth of the at least two second auxiliary buffer sections.

21. The display device of claim 20, wherein the depth of the second buffer section is different than the depth of the first buffer section.

22. The display device of claim 13, wherein the substrate includes a first bending region at a portion having the first buffer section, a second bending region at a portion having the at least two first auxiliary buffer section, a third bending region at a portion having the second buffer section, and a fourth bending region at a portion having the at least two second auxiliary buffer section; and
wherein a curvature of the first bending region is greater than a curvature of the third bending region in a folded state of the display device.
